(19) United States
(12) Patent Application Publication
(10) Pub. No.: US 2012/0161260 A1
(43) Pub. Date: Jun. 28, 2012

(54) Method for packaging a sensor chip, and a component produced using such a method

(76) Inventors: Uwe HANSEN, Tuebingen (DE); Lutz Rauscher, Reutlingen (DE)

(21) Appl. No.: 13/334,398

(22) Filed: Dec. 22, 2011

(30) Foreign Application Priority Data
Dec. 23, 2010 (DE) 10 2010 064 108.1

(51) Int. Cl. H01L 29/84; H01L 29/66; H01L 21/56

(52) U.S. Cl. 257/416; 438/127; 257/417; 438/51; 438/55; 257/467; 257/E21.504; 257/E29.324; 257/E29.347

(57) ABSTRACT

Measures are introduced to make possible a low-cost packaging of sensor chips having a media access. For this purpose, the sensor chip is first mounted on a substrate and is contacted. The sensor chip is then at least partially embedded in a molding compound. Finally, at least one portion of the media access is produced by the subsequent structuring of the molding compound.

### RELATED APPLICATION INFORMATION

The present application claims priority to and the benefit of German patent application no. 10 2010 064 108.1, which was filed in Germany on Dec. 23, 2010, the disclosure of which is incorporated herein by reference.

### FIELD OF THE INVENTION

The present invention relates to the packaging of sensor chips which require a media access. These can be pressure sensors or the special implementation thereof as microphones, or also optical sensors used for gas analysis, such as CO2 gas detectors, for example, or thermal sensors for measuring temperature and heat flux, which are generally referred to as thermopiles.

### BACKGROUND INFORMATION

It is intended that a packaging protect the sensor chip from mechanical and chemical environmental effects. Moreover, the type of packaging, respectively the type of housing determines how the sensor chip can be mounted and contacted in situ. Accordingly, a seemingly wide array of packaging variants for sensor chips are discussed the related art.

In the case of an MEMS microphone component, the housing additionally takes on some of the microphone functionality since both the acoustic connection, as well as the rear-side volume of the microphone membrane are determined to a large degree by the housing design. Since the packaging considerably influences the transmission characteristic of an MEMS microphone, the known packaging variants for microphone chips mostly involve relatively complex and costly specialized approaches.

### SUMMARY OF THE INVENTION

The exemplary embodiments and/or exemplary methods of the present invention provides measures which make possible a low-cost packaging of sensor chips having a media access.

To this end, the packaging concept according to the present invention provides for the sensor chip to be first mounted on a substrate and to be contacted there. The sensor chip is then at least partially embedded in a molding compound. Only subsequently thereto is at least one portion of the media access produced by the later structuring of the molding compound.

In practice, mold housings have proven to be very rugged and simple to manufacture. The exemplary embodiments and/or exemplary methods of the present invention provide for this packaging concept to also be used for sensor chips which require a media access. The exemplary embodiments and/or exemplary methods of the present invention have, namely, recognized that such a media access may be realized in a mold housing, at least in portions thereof, using standard methods, as are used to produce plated-through holes for housings, which are generally referred to as through-mold vias (TMV). It is only through the use of this structuring method, which has been developed in a completely different technical context, is it possible to cost-effectively implement a mold housing for the sensor chips of the type discussed here.

The media access may be readily produced by boring the molding compound or also with the aid of a laser structuring method, as is used within the framework of the TMV process. In contrast to the TMV process, in which a mold substrate is provided with through holes, it is intended that the molding compound of the sensor chip packaging merely be structured to a predefined depth during fabrication of a media access. A metal layer is advantageously integrated in the packaging as a defined limitation for the laser structuring.

As already discussed above, the present invention may be advantageously embodied and further refined in various ways. To this end, reference is made, on the one hand, to the claims that are subordinate to the independent claims and, on the other hand, to the following description of two exemplary embodiments of the present invention with reference to the figures.

### BRIEF DESCRIPTION OF THE DRAWINGS

FIG. 1a, 1b, and 1c illustrate the configuration of a first sensor chip packaging according to the present invention with reference to schematic cross-sectional representations.

FIGS. 2a, 2b, 2c, and 2d illustrate the configuration of a second sensor chip packaging according to the present invention with reference to schematic cross-sectional representations.

### DETAILED DESCRIPTION

The two exemplary embodiments described in the following each relate to the packaging of an MEMS microphone chip having a microphone membrane, which needs to be connected to the acoustic access channel in the packaging.

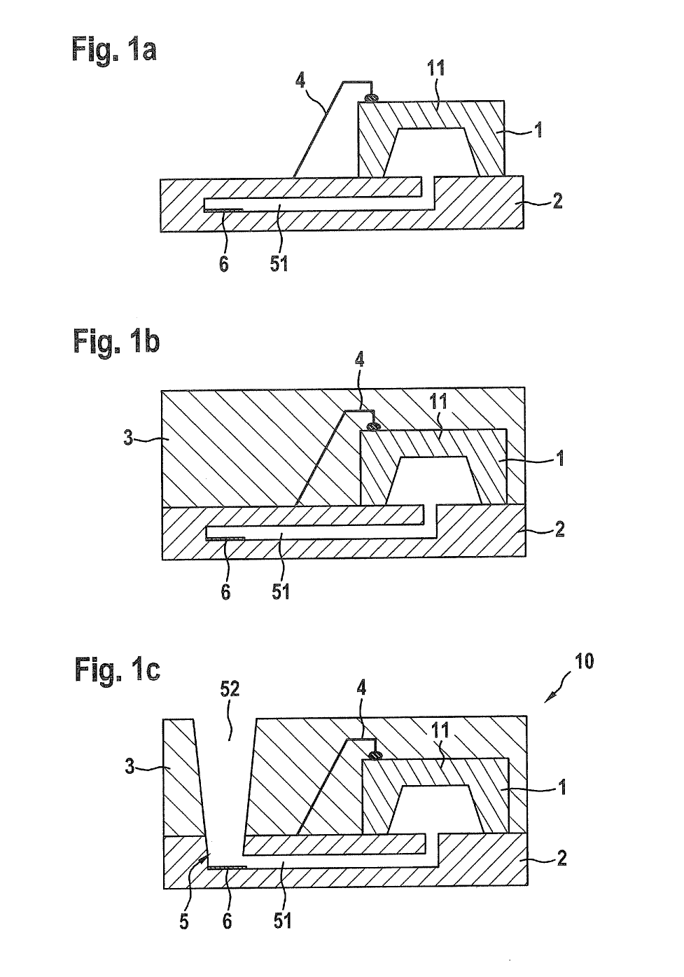

FIG. 1a shows such a microphone chip 1 after it has been mounted face-up, thus with the component rear side on a planar substrate 2, and has been electrically contacted with the aid of bonding wires 4. In the present case, a first portion 51 of an acoustic access channel 5 is formed within substrate 2.

This portion 51 of acoustic access channel 5 extends in parallel to the substrate plane and opens through into an opening 50 in the substrate surface. Microphone chip 1 is configured on substrate 2 in a way that allows microphone membrane 11 to be positioned directly over opening 50. Moreover, it is discernible in FIG. la that the bottom area of first portion 51 of acoustic access channel 5 is provided with a metal layer 6, at least in one region laterally next to microphone chip 1.

Once microphone chip 1 has been mounted and contacted on thus prepared substrate 2, it is embedded, together with bonding wires 4, in a molding compound 3 suited for defining the microphone package design. In this context, it is necessary to provide a rear-side volume for microphone membrane 11 that is sealed against the conduction of sound. FIG. 1b shows the microphone package following the molding process, the rear side volume not being shown in detail here.

Only subsequently thereto is the already cured molding compound 3 structured in order to expose acoustic access channel 5. To this end, a bore 52, originating at the top side of the package and extending to first portion 51 of acoustic access channel 5 in substrate 2, leading into the same, is introduced into molding compound 3. In the exemplary embodiment illustrated here, bore 52 is produced with the aid of a laser structuring method, as is used for fabricating through-mold vias for package-on-package housings. Metal layer 6 of acoustic access channel portion 51 in the orifice region of bore 52 forms a stop layer for the laser structuring and thus constitutes a depth limitation for bore 52. Together with portion 51, bore 52 then forms acoustic access channel 5 of microphone package 10, which is illustrated in FIG. 1c.

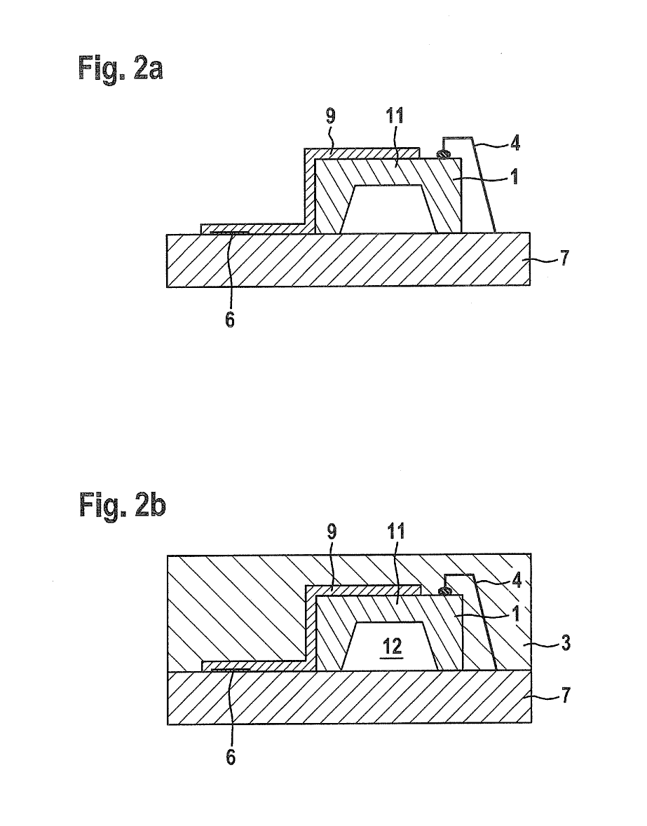

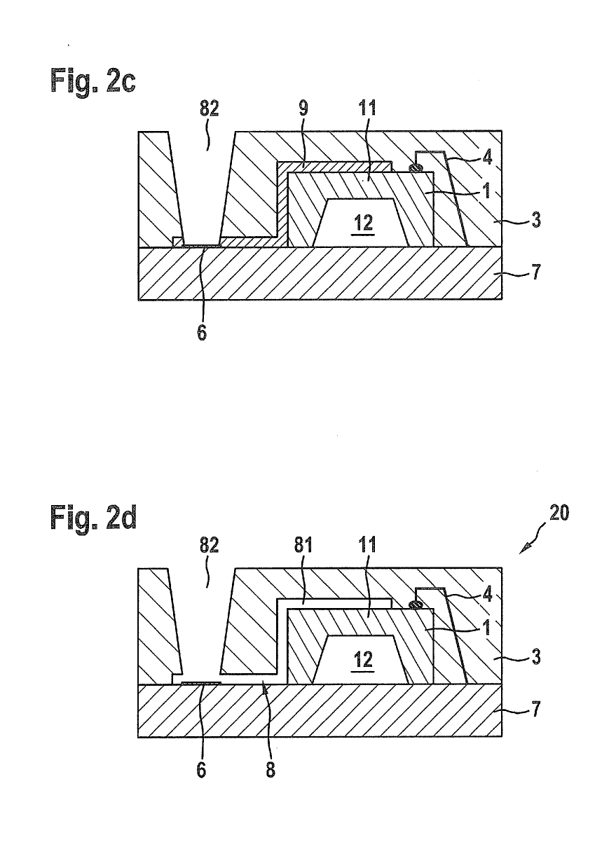

As in the case of first packaging variant described above, microphone chip 1 is also mounted face-up on a planar substrate 7 in the case of second packaging variant illustrated in FIG. 2a through 2d, and is electrically contacted with the aid of bonding wires 4. In this case, however, it is intended that the sound be conducted to the top side of microphone membrane 11. Accordingly, in contrast to the first packaging variant, no specially prepared and already structured substrate is needed here. Rather, all portions of acoustic access channel 8 are produced in molding compound 3 that encases microphone chip 1.

To this end, substrate 7 is provided with a metal layer 6 in a region next to the mounting surface of microphone chip 1. Once microphone chip 1 is mounted, a layer of a chemically desorbing polymer 9 is then applied to populated substrate 7, which, on the one hand, extends over metal layer 6 and, on the other hand, to over microphone membrane 11 of microphone chip 1, as is illustrated in FIG. 2a. This polymer layer 9 functions as a “place holder” for a first portion 81 of sound access channel 8.

Subsequently thereto, microphone chip 1, together with bonding wires 4, is embedded in a molding compound 3 suited for defining the microphone package design. Rear-side volume 12 is enclosed here between microphone membrane 11 and substrate 7, as is illustrated by FIG. 2b.

As in the case of the first packaging variant, sound access channel 8 is exposed by the laser structuring of already cured molding compound 3, in that a bore 82 is introduced into molding compound 3. This bore 82 extends from the top side of the package to metal layer 6 on the substrate surface, as is illustrated in FIG. 2c.

FIG. 2d shows the microphone package following a desorption step in which polymer 9 was removed. Portion 81 is thereby exposed. Together with bore 82, it now forms sound access channel 8 of microphone package 20.

What is claimed is:

1. A method for fabricating a packaging having media access for a sensor chip, the method comprising:
mounting and contacting the sensor chip on a substrate;
at least partially embedding the sensor chip in a molding compound; and
producing at least one portion of the media access by a subsequent structuring of the molding compound.

2. The method of claim 1, wherein at least one portion of the media access includes a bore in the molding compound.

3. The method of claim 1, wherein a metal layer is integrated in the packaging, and wherein at least one portion of the media access is produced by the laser structuring of the molding compound, and wherein the metal layer is used as a depth limitation for the structuring.

4. A component, comprising:
a sensor chip;
a substrate on which the sensor chip is mounted and contacted;
a molding compound in which the sensor chip is at least partially embedded; and
a media access arrangement to provide media access to the sensor chip;
wherein at least one portion of the media access arrangement is produced by a subsequent structuring of the molding compound.

5. The component of claim 4, wherein at least one portion of the media access is bored into the molding compound.

6. The component of claim 4, wherein at least one portion of the media access opens through to a metal layer integrated in the packaging.

7. The component of claim 4, wherein the sensor chip includes one of a pressure sensor chip, a microphone chip, an optical sensor chips used for gas analysis, and a sensor chip used for measuring at least one of temperature and heat flux.

8. The component of claim 4, wherein the sensor chip is a MEMS microphone chip.

9. The method of claim 1, wherein the sensor chip is a MEMS microphone chip.

10. The method of claim 1, wherein the sensor chip includes one of a pressure sensor chip, a microphone chip, an optical sensor chips used for gas analysis, and a sensor chip used for measuring at least one of temperature and heat flux.
